(19) United States
(12) Patent Application Publication
(10) Pub. No.: US 2005/0009373 A1
(43) Pub. Date: Jan. 13, 2005

(54) Semiconductor device and method for preventing damage to anti-reflective structure during removing an overlying photoresist layer

(76) Inventors: Tien-I Bao, Hsinchu (TW); Syun-Ming Jang, Hsinchu (TW)

Correspondence Address: THOMAS, KAYDEN, HOSTEMEYER & RISLEY LLP, 100 GALLERIA PARKWAY, SUITE 1750, ATLANTA, GA, 30339, US

(21) Appl. No.: 10/618,527

(22) Filed: Jul. 11, 2003

(51) Int. Cl. H01L 21/20; H01L 21/36; H01L 21/4763

(52) U.S. Cl. 438/787; 438/786; 438/636; 438/952

(57) ABSTRACT

A method for preventing damage to an anti-reflective structure during removing an overlying photoresist layer. A nitrogen-free silicon oxide layer having a refractive index of 1.4˜1.7 and an extinction coefficient of 0˜0.5 is in-situ formed overlying a nitrogen-free dielectric anti-reflective structure to serve as a protective layer. A patterned photoresist layer is formed overlying the nitrogen-free silicon oxide layer. The patterned photoresist layer is removed by oxygen containing plasma. A semiconductor device for preventing damage to an anti-reflective structure during removing an overlying photoresist layer is also disclosed.

### BACKGROUND OF THE INVENTION

1. Field of the Invention

The invention relates to lithography and more particularly to a semiconductor device and method for preventing damage to an anti-reflective structure during removing an overlying photoresist.

2. Description of the Related Art

Lithography is generally used to form a desired circuit pattern on a semiconductor substrate, such as a silicon wafer, or on a specific layer formed overlying the semiconductor substrate during the fabrication process. Lithography is typically performed by coating a photoresist material onto the substrate which triggers a photo-chemical reaction on the semiconductor substrate. After coating the substrate with a photoresist material, a soft baking step is performed to remove the solvent from the photoresist material. Thereafter, the photoresist material is exposed and developed to create a photoresist layer with a desired feature pattern overlying the substrate. The patterned photoresist layer serves as an etching mask to selectively etch the semiconductor substrate or the specific layer formed thereon. If the lithography results in an incorrect pattern, such as a critical dimension (CD) variation or mispatterning, the photoresist coating overlying the semiconductor substrate must be completely removed, and a new photoresist layer must be recoated onto the substrate in order to create a new pattern. This is typically referred to as photoresist rework.

Photoresist rework is economically desirable alternative to abandoning the wafer. However, during stripping of the photoresist layer, the underlying anti-reflective layer (ARL) may be damaged by oxygen containing plasma. For example, the ARL may be further oxidized due to reaction with oxygen from plasma used during stripping, resulting in altering the original refractive index and extinction coefficient of the anti-reflective material causing the ARL to fail.

A conventional method of fabrication of a semiconductor device having a double layer type anti-reflective layer is disclosed in U.S. Pat. No. 6,352,922. This patent discloses a method employing a nitride layer and an overlying layer formed using only hydrocarbon-based gas as the double layer type ARL which can reduce reflectivity in lithography. However, it fails to take into consideration ARL damage during reworking of a photoresist layer.

### SUMMARY OF THE INVENTION

Accordingly, an object of the present invention is to provide a semiconductor device and method for preventing damage to an anti-reflective structure during removing an overlying photoresist, which uses a silicon oxide layer to protect the underlying anti-reflective structure from plasma damage, thereby preventing change in the refractive index and extinction coefficient of the anti-reflective structure.

According to the object of the invention, a method for preventing damage to an anti-reflective structure during removing an overlying photoresist layer includes the following steps. First, a nitrogen-free silicon oxide layer having a refractive index of 1.4˜1.7 and an extinction coefficient of 0˜0.5 is in-situ formed overlying a nitrogen-free dielectric anti-reflective structure to serve as a protective layer. Next, a patterned photoresist layer is formed overlying the nitrogen-free silicon oxide layer. Finally, the patterned first photoresist layer is removed by oxygen containing plasma.

Moreover, the nitrogen-free silicon oxide layer is in-situ formed by plasma enhanced chemical vapor deposition (PECVD) using SiH₄ and CO₂ as process gases. The nitrogen-free silicon oxide layer, which has a thickness of about 10˜500 Å, can be a silicon dioxide layer or a silicon oxycarbide layer.

The present invention also provides a semiconductor device for preventing damage to an anti-reflective structure during removing an overlying photoresist layer. The device includes a nitrogen-free dielectric anti-reflective structure and a nitrogen-free silicon oxide layer. The nitrogen-free dielectric anti-reflective structure is disposed overlying a substrate. The nitrogen-free silicon oxide layer, which has a refractive index of 1.4˜1.7 and an extinction coefficient of 0˜0.5, is disposed overlying the nitrogen-free anti-reflective layer to serve as a protective layer.

Moreover, the nitrogen-free silicon oxide layer is in-situ formed by plasma enhanced chemical vapor deposition (PECVD) using SiH₄ and CO₂ as process gases. The nitrogen-free silicon oxide layer, which has a thickness of about 10˜500 Å, can be a silicon dioxide layer or a silicon oxycarbide layer.

### DESCRIPTION OF THE DRAWINGS

The present invention will become more fully understood from the detailed description given hereinbelow and the accompanying drawings, given by way of illustration only and thus not intended to be limitative of the present invention.

FIGS. 1a to 1f are cross-sections showing a method flow for preventing anti-reflective structure damage by removing an overlying photoresist according to the invention.

### DETAILED DESCRIPTION OF THE INVENTION

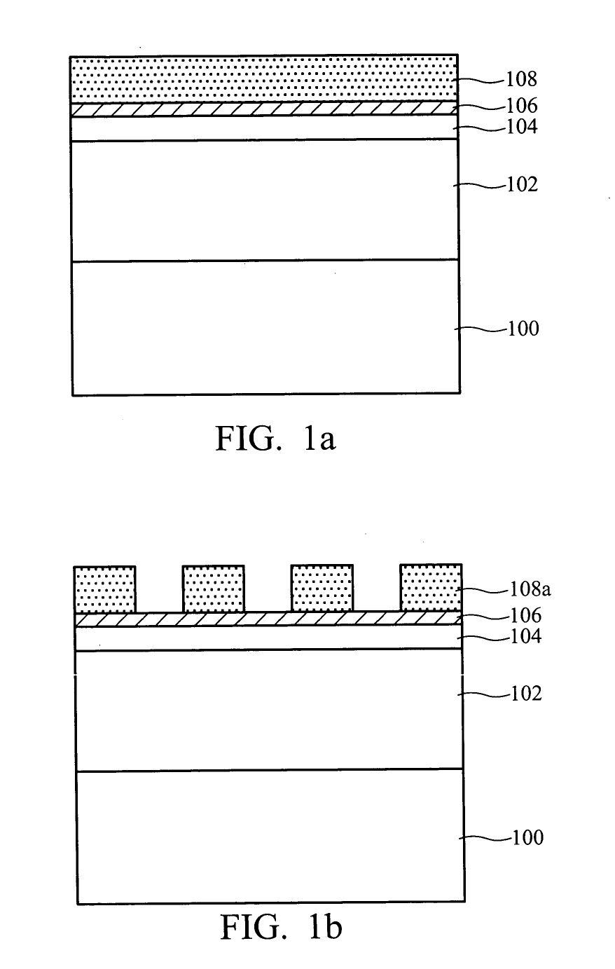

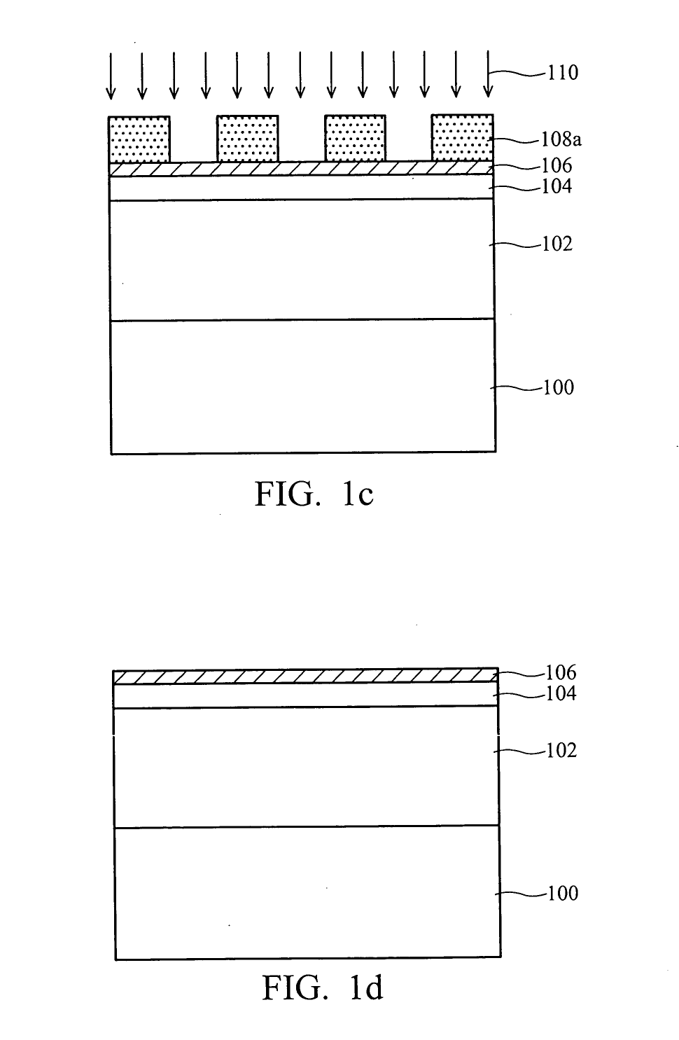

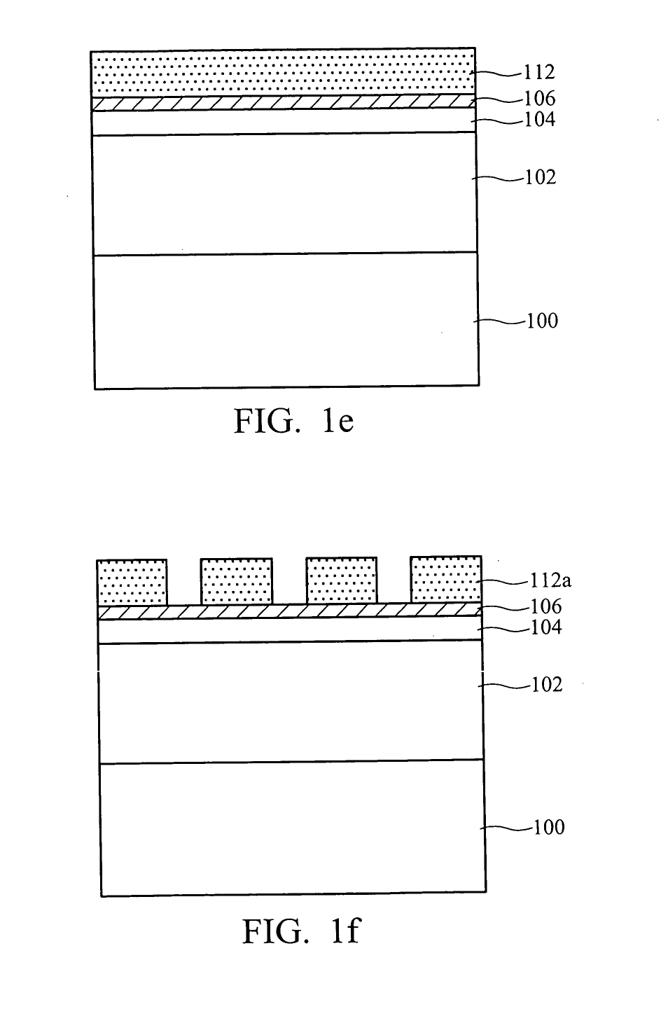

FIGS. 1a to 1f are cross-sections illustrating the method flow for preventing anti-reflective structure damage by removing an overlying photoresist according to the invention. First, in FIG. 1a, a substrate 100, such as a silicon wafer, is provided. The substrate 100 may contain a variety of elements, including, for example, transistors, diodes, and other semiconductor elements as are well known in the art. The substrate 100 may also contain other metal interconnect layers. In order to simplify the diagram, a flat substrate is depicted. A layer to be defined 102 is deposited overlying the substrate 100. In the invention, the layer to be defined 102 may be a conductive layer, such as a doped polysilicon layer or other well known metal layer used in the fabrication of semiconductor devices. Moreover, the layer to be defined 102 can be a dielectric layer to serve as an interlayer dielectric (ILD) layer or an intermetal dielectric (IMD) layer. For example, the dielectric layer may be silicon dioxide, phosphosilicate glass (PSG), borophosphosilicate glass (BPSG), or low-k material, such as fluorosilicate glass (FSG).

Next, an anti-reflective structure 104, for example, an anti-reflective layer (ARL), is deposited overlying the layer to be defined 102. The ARL 104 may be silicon oxynitride (SiON) formed by chemical vapor deposition (CVD) using, for example, SiH₄, O₂, and N₂ as process gases. Moreover, the ARL 104 may be a nitrogen-free dielectric anti-reflective coating (DARC) layer such as silicon rich oxide (SiOₓ), where x<2, formed by CVD using, for example, SiH₄ and O₂ as process gases.

Next, a thin nitrogen-free silicon oxide layer 106 is formed overlying the ARL 104. In the invention, the nitrogen-free silicon oxide layer 106 may be a completely oxidized material such as silicon dioxide or silicon oxycarbide (SiOC). The thin nitrogen-free silicon oxide layer 106 has a thickness of about 10˜500 Å. Preferably, the nitrogen-free silicon oxide layer 106 has a thickness of about 50 Å.

Moreover, the nitrogen-free silicon oxide layer 106 can be formed by conventional deposition, such as plasma enhanced chemical vapor deposition (PECVD), low pressure chemical vapor deposition (LPCVD), atmospheric pressure chemical vapor deposition (APCVD), high density plasma chemical vapor deposition (HDPCVD) or other suitable CVD. In the invention, the nitrogen-free silicon oxide layer 106 is formed by PECVD using at least one of the following gases SiH₄, Si₂H₆, tetramethylsilane (4MS), trimethylsilane (3MS), and tetraethyl orthosilicate (TEOS) as a first process gas to provide silicon atoms and using at least one of the following gases CO₂, O₂, and H₂O as a second process gas to provide oxygen atoms. Preferably, the first process gas is SiH₄ and the second process gas is CO₂. Moreover, Helium, argon or another inert gas can be used as a carrier gas. In addition, it is noted that if the ARL 104 is a nitrogen-free DARC layer, the thin nitrogen-free silicon oxide layer 106 can be in-situ formed by PECVD, thereby further simplifying the process steps and reducing the fabrication time.

The thin nitrogen-free silicon oxide layer 106 has a refractive index within a range of 1.4˜1.7, and preferably 1.4˜1.5. Moreover, the nitrogen-free silicon oxide layer 106 has an extinction coefficient of about 0˜0.5. Here, the nitrogen-free silicon oxide layer 106 is used as a protective layer to avoid the ARL 104 damage during plasma stripping an overlying photoresist pattern layer.

Next, an energy sensitive layer 108, such as a positive or negative photoresist material, is coated overlying the nitrogen-free silicon oxide layer 106 by a conventional process, for example, spin coating, and then the energy sensitive layer 108 is curried. Thereafter, in FIG. 1b, the photoresist layer 108 is patterned by conventional lithography to form a patterned photoresist layer 108a having any desired pattern therein. Next, the patterned photoresist layer 108a is examined to determine whether or not it has the desired feature pattern. For example, the width of the lines within the patterned photoresist layer 108a or space between the lines with the same is determined to be within the specification or not by after development inspection (ADI). If the line width or line space is within the specification, the fabrication of semiconductor devices proceeded with subsequent process.

To the contrary, if the line width or line space is out of specification, the patterned photoresist layer 108a is removed for rework. In FIG. 1c, the patterned photoresist layer 108a having an undesirable feature pattern is stripped by oxygen containing plasma 110. FIG. 4 shows the structure after the patterned photoresist layer 108a is completely removed. During stripping, the portion of underlying anti-reflective structure uncovered by the patterned photoresist layer 108a may be damaged. For example, incompletely oxidized anti-reflective materials may react with the oxygen containing plasma, altering its original optical properties such as refractive index and the extinction coefficient, making the anti-reflective structure fail. In the invention, the nitrogen-free silicon oxide layer 106 overlying the ARL 104 is used as a protective layer to create a barrier preventing the oxygen atoms from the plasma 110 from reacting with the ARL 104. Accordingly, the undamaged underlying ARL 104 maintains its original refractive index and extinction coefficient, and thereby improves the lithography quality.

Next, in FIG. 1e, another energy sensitive layer 112, such as a positive or negative photoresist material, is coated over the nitrogen-free silicon oxide layer 106 and curried by a conventional process.

Finally, in FIG. 1f, the photoresist layer 112 is patterned by lithography to form a patterned photoresist layer 112a having a desired feature pattern therein.

FIG. 1d also shows a semiconductor device for preventing damage to an anti-reflective structure during removing an overlying photoresist layer. The device includes a substrate 100 having a layer to be defined 102 thereon. A nitrogen-free dielectric anti-reflective structure 104 is disposed overlying the layer to be defined 102. Moreover, a thin nitrogen-free silicon oxide layer 106, which has a refractive index of 1.4˜1.7 and an extinction coefficient of about 0˜0.5, is disposed overlying the nitrogen-free anti-reflective layer 104 to serve as a protective layer. The nitrogen-free silicon oxide layer 106 may be silicon dioxide or silicon oxycarbide (SiOC). The thin nitrogen-free silicon oxide layer 106 has a thickness of about 10˜500 Å. Preferably, the nitrogen-free silicon oxide layer 106 has a thickness of about 50 Å. Moreover, the nitrogen-free silicon oxide layer 106 can be formed by conventional deposition, such as plasma enhanced chemical vapor deposition (PECVD).

According to the invention, since the ARL can be protected from plasma damage by an overlying oxide layer, lithography quality can be increased by maintaining the optical properties of the ARL, thereby increasing the subsequent etching.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method for preventing damage to an anti-reflective structure during removing an overlying photoresist layer, comprising the steps of:
forming a nitrogen-free silicon oxide layer having a refractive index of 1.4˜1.7 and an extinction coefficient of 0˜0.5 overlying the anti-reflective structure to serve as a protective layer;
forming a patterned photoresist layer overlying the nitrogen-free silicon oxide layer; and
removing the patterned photoresist layer.

2. The method as claimed in claim 1, wherein the anti-reflective structure contains no nitrogen.

3. The method as claimed in claim 1, wherein the anti-reflective structure consists at least one silicon oxynitride layer.

4. The method as claimed in claim 1, wherein the nitrogen-free silicon oxide layer is formed by plasma enhanced chemical vapor deposition.

5. The method as claimed in claim 4, wherein the nitrogen-free silicon oxide layer is formed from SiH₄ and CO₂.

6. The method as claimed in claim 4, wherein the third insulating spacer is removed by buffer oxide etch solution (BOE).

7. (cancelled)

8. The method as claimed in claim 1, wherein the nitrogen-free silicon oxide layer is a silicon dioxide layer.

9. The method as claimed in claim 1, wherein the nitrogen-free silicon oxide layer is a silicon oxycarbide layer.

10. A method for preventing damage to an anti-reflective structure during removing an overlying photoresist layer, comprising the steps of:
in-situ formation of a nitrogen-free silicon oxide layer having a refractive index of 1.4˜1.7 and an extinction coefficient of 0˜0.5 overlying a nitrogen-free dielectric anti-reflective structure to serve as a protective layer;
forming a patterned photoresist layer overlying the nitrogen-free silicon oxide layer; and
removing the patterned photoresist layer.

11. The method as claimed in claim 10, wherein the nitrogen-free silicon oxide layer is in-situ formed by plasma enhanced chemical vapor deposition.

12. The method as claimed in claim 11, wherein the nitrogen-free silicon oxide layer is formed from SiH₄ and CO₂.

13. The method as claimed in claim 10, wherein the nitrogen-free silicon oxide layer has a thickness of about 10˜500 Å.

14. The method as claimed in claim 10, wherein the nitrogen-free silicon oxide layer is a silicon dioxide layer.

15. The method as claimed in claim 10, wherein the nitrogen-free silicon oxide layer is a silicon oxycarbide layer.

16. A semiconductor device for preventing damage to an anti-reflective structure during removing an overlying photoresist layer, comprising:
a nitrogen-free dielectric anti-reflective structure disposed overlying a substrate; and
a nitrogen-free silicon oxide layer having a refractive index of 1.4˜1.7 and an extinction coefficient of 0˜0.5 disposed overlying the nitrogen-free anti-reflective layer to serve as a protective layer.

17. (cancelled):

18. The semiconductor device as claimed in claim 16, wherein the nitrogen-free silicon oxide layer is a silicon dioxide layer.

19. The semiconductor device as claimed in claim 16, wherein the nitrogen-free silicon oxide layer is a silicon oxycarbide layer.

20. The semiconductor device as claimed in claim 16, wherein the nitrogen-free silicon oxide layer has a thickness of about 10˜Å.
